(19) United States
(12) Patent Application Publication
(10) Pub. No.: US 2024/0282831 A1
(43) Pub. Date: Aug. 22, 2024

(54) FIELD EFFECT TRANSISTOR

(71) Applicant: Skyworks Solutions, Inc., Irvine, CA (US)

(72) Inventor: Guillaume Alexandre Blin, Carlisle, MA (US)

(21) Appl. No.: 18/443,016

(22) Filed: Feb. 15, 2024

Related U.S. Application Data
(60) Provisional application No. 63/446,111, filed on Feb. 16, 2023.

(51) Int. Cl. H01L 29/417; H01L 23/48; H01L 27/06; H01L 29/20; H01L 29/40; H01L 29/778

(52) U.S. Cl. CPC H01L 29/41758; H01L 23/481; H01L 27/0629; H01L 28/40; H01L 29/2003; H01L 29/402; H01L 29/7786

(57) ABSTRACT

A power amplifier can include at least one field effect transistor integrated within an associated transistor area. The transistor has transistor contacts with a contact configuration of cascoded contact fingers. The contact fingers include a source contact finger, a drain contact finger, a first gate contact finger provided between the source contact finger and the drain contact finger, and a second gate contact finger provided between the source contact finger and the drain contact finger.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

The present disclosure generally relates to an improved field effect transistor which can be used in radio frequency applications.

### Description of Related Technology

Field effect transistors are widely used in many technical applications such as 5G telecommunication applications. Field effect transistors can be used in power amplifiers implemented in radio frequency modules of wireless devices.

### SUMMARY

The innovations described in the claims each have several aspects, no single one of which is solely responsible for its desirable attributes. Without limiting the scope of the claims, some prominent features of this disclosure will now be briefly described.

According to several aspects of the disclosure, a field effect transistor, FET, integrated within an associated transistor area is disclosed. The FET comprises transistor contacts having a contact configuration of cascoded contact fingers. The cascoded contact fingers include a first gate contact finger provided between a source contact finger and a drain contact finger. The cascoded contact fingers also include a second gate contact finger provided between the source contact finger and the drain contact finger.

The cascoded contact fingers of the contact configuration can comprise a rectangular shape.

The first gate contact finger can have a different shape than the second gate contact finger. The first gate contact finger can have a different channel length than the second gate contact finger. In particular, the first gate contact finger can have a shorter channel length than the second gate contact finger. For example, the voltage between a drain contact finger and a source contact finger can be limited by the second gate contact finger. The first gate contact finger would not require as high voltage handling. As a result, the first gate contact finger can have higher gain, higher operating frequency, and higher bandwidth due to the higher Ft. The second gate contact finger would require to withstand most of the DC and RF swing and therefore can have at least one of the group consisting of higher gate channel length and gate and source connected field plates to accommodate the high voltage.

At least one of the first gate contact finger and the second gate contact finger can comprise a T-shape.

The transistor contacts can comprise a source contact located on a back side of a die, the source contact connected by a through wafer via, TWV, to the source contact finger.

The transistor contacts can comprise a metal-insulator-metal, MIM, capacitor arranged between the source finger and a second gate contact including the second gate contact finger.

The FET can comprise a wide bandgap transistor. In particular, the wide bandgap transistor can comprise a Gallium Nitride, GaN, transistor.

The FET can comprise a gallium nitride, GaN, a gallium arsenide, GaAs, or other compound semiconductor transistor.

The FET can comprise a pseudomorphic high-electron-mobility transistor, pHEMT.

The first gate contact finger can be arranged closer to the source contact finger than the second gate contact finger. Additionally, the second gate contact finger can be arranged closer to the drain contact finger than the first gate contact finger.

The transistor contacts can comprise a first gate contact including a first pad for external bias connected to the first gate contact finger.

The transistor contacts can comprise a second gate contact including a second pad for external bias connected to the second gate contact finger.

The transistor contacts can comprise a source connected field plate.

In some aspects of the disclosure, a power amplifier is disclosed. The power amplifier comprises at least one field effect transistor, FET, integrated within an associated transistor area. The FET comprises transistor contacts have a contact configuration of cascoded contact fingers. The cascoded contact fingers include a first gate contact finger provided between a source contact finger and a drain contact finger. The cascoded contact fingers also include a second gate contact finger provided between the source contact finger and the drain contact finger.

The cascoded contact fingers of the contact configuration can comprise a rectangular shape.

The first gate contact finger can have a different shape than the second gate contact finger. The first gate contact finger can have a different channel length than the second gate contact finger. In particular, the first gate contact finger can have a shorter channel length than the second gate contact finger. For example, the voltage between a drain contact finger and a source contact finger can be limited by the second gate contact finger. The first gate contact finger would not require as high voltage handling. As a result, the first gate contact finger can have higher gain, higher operating frequency, and higher bandwidth due to the higher Ft. The second gate contact finger would require to withstand most of the DC and RF swing and therefore can have at least one of the group consisting of higher gate channel length and gate and source connected field plates to accommodate the high voltage.

At least one of the first gate contact finger and the second gate contact finger can comprise a T-shape.

The transistor contacts can comprise a source contact located on a back side of a die, the source contact connected by a through wafer via, TWV, to the source contact finger.

The transistor contacts can comprise a metal-insulator-metal, MIM, capacitor arranged between the source finger and a second gate contact including the second gate contact finger.

The FET can comprise a wide bandgap transistor. In particular, the wide bandgap transistor can comprise a Gallium Nitride, GaN, transistor.

The FET can comprise a gallium nitride, GaN, a gallium arsenide, GaAs, or other compound semiconductor transistor.

The FET can comprise a pseudomorphic high-electron-mobility transistor, pHEMT.

The first gate contact finger can be arranged closer to the source contact finger than the second gate contact finger. Additionally, the second gate contact finger can be arranged closer to the drain contact finger than the first gate contact finger.

The transistor contacts can comprise a first gate contact including a first pad for external bias connected to the first gate contact finger.

The transistor contacts can comprise a second gate contact including a second pad for external bias connected to the second gate contact finger.

The transistor contacts can comprise a source connected field plate.

In a number of aspects of the disclosure, a wireless device is disclosed. The wireless device comprises a transceiver configured to process radio frequency signals. The wireless device further comprises a radio frequency module including at least one field effect transistor, FET, integrated within an associated transistor area. The FET comprises transistor contacts have a contact configuration of cascoded contact fingers. The cascoded contact fingers include a first gate contact finger provided between a source contact finger and a drain contact finger. The cascoded contact fingers also include a second gate contact finger provided between the source contact finger and the drain contact finger.

The wireless device can further comprise an antenna connected to the radio frequency module.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a cross-section view of a field effect transistor layout.

FIG. 1B shows a cross-section view of a field effect transistor according to an embodiment in comparison to the field effect transistor layout of FIG. 1A.

FIG. 2 shows a schematic top view diagram of a field effect transistor according to another embodiment.

FIGS. 3A, 3B show a schematic top view diagram of a field effect transistor according to another embodiment with a through wafer via.

FIG. 4A shows a schematic top view diagram of a field effect transistor according to another embodiment with a pad for external bias connected to the gate contact fingers.

FIG. 4B shows a schematic top view diagram of a field effect transistor according to another embodiment with a pad for external bias connected to the gate contact fingers and with a metal-insulator-metal capacitor.

FIGS. 5A, 5B show a schematic top view diagram of a field effect transistor according to another embodiment.

FIG. 6 shows a cross-section view of a field effect transistor according to another embodiment.

FIG. 7 shows a schematic diagram of an example wireless device having one or more advantageous features described herein.

### DETAILED DESCRIPTION OF EMBODIMENTS

The following detailed description of certain embodiments presents various description of specific embodiments. However, the innovation described herein can be embodied in a multiple of different ways, for example, as defined and covered by the claims. In this description, reference is made to the drawings where like reference numbers can indicate identical or functionally similar elements. It will be understood that elements illustrated in the figures are not necessarily drawn to scale. Moreover, it will be understood that certain embodiments can include more elements than illustrated in a drawing and/or in a subset of the elements illustrated in a drawing. Further, some embodiments can incorporate any suitable combination of features from two or more drawings.

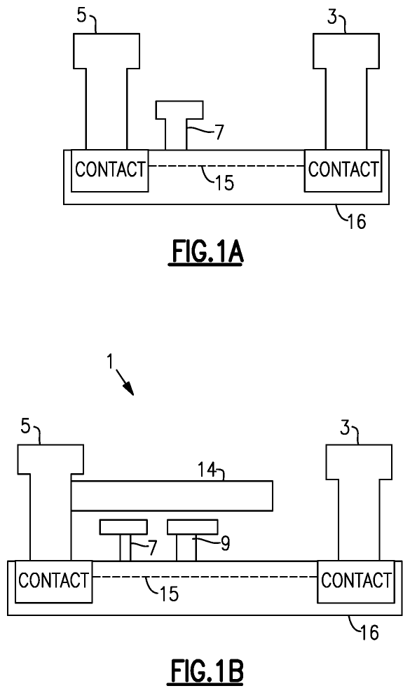

FIG. 1A shows a cross-section view of a field effect transistor layout. The field effect transistor layout typically comprises a drain contact finger 3, a source contact finger 5 and a gate contact finger 7 provided between the drain contact finger 3 and the source contact finger 5. The field effect transistor layout may include a substrate 16. The substrate 16 can comprise an electrically conductive channel 15 for electrically coupling the drain contact finger 3 and the source contact finger 5.

FIG. 1B shows a cross-section view of a field effect transistor 1 according to an embodiment in comparison to the field effect transistor layout of FIG. 1A. The layout of the field effect transistor 1 is illustrated in comparison to a die layout of a field effect transistor as illustrated in FIG. 1A.

The field effect transistor 1 comprises transistor contacts. The transistor contacts can include a drain contact finger 3, a source contact finger 5 as well as a first gate contact finger 7 and a second gate contact finger 9 both provided between the drain contact finger 3 and the source contact finger 5. The field effect transistor 1 exemplarily includes a substrate 16. The substrate 16 can comprise an electrically conductive channel 15 for electrically coupling the drain contact finger 3 and the source contact finger 5. For example, the substrate 16 can have a gallium nitride (GaN) layer on which the transistor contacts are disposed. An evaporation process can be employed to create the transistor contacts.

Optionally, the transistor contacts and the field effect transistor 1, respectively, can comprise a source connected field plate 14. At least one of the first gate contact finger 7 and the second gate contact finger 9 comprises a T-shape. Here, both the first gate contact finger 7 and the second gate contact finger 9 exemplarily comprise a T-shape.

Higher frequency amplifiers comprising field effect transistors can benefit from shorter gate length, which limits a maximum supply and an output power of the power amplifier. A field effect transistor layout according to the embodiments described herein can mitigate this issue.

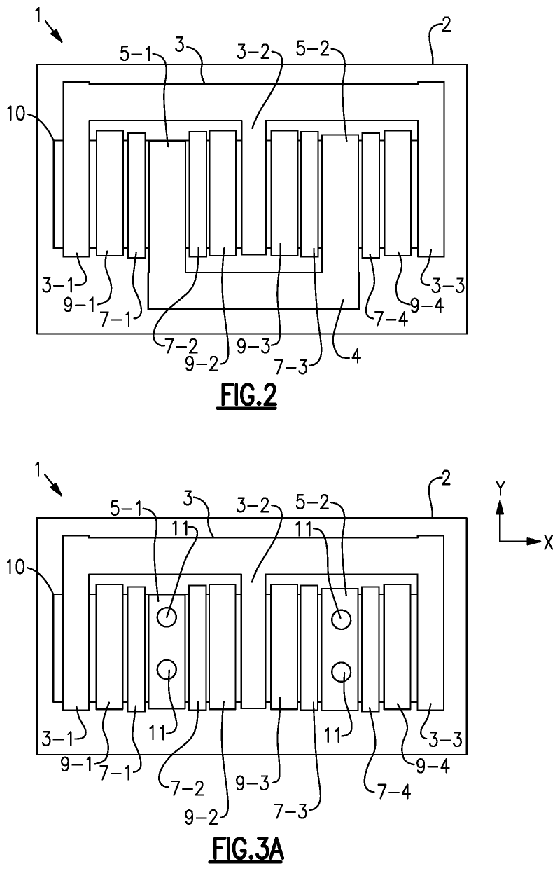

By comparing the layout of the field effect transistor 1 according to FIG. 1B to the field effect transistor layout shown in FIG. 1A, and with further reference to FIG. 2, for example, it can be seen that the first gate contact finger 7 and the second gate contact finger 9 are arranged in the same active region 10 of a transistor area 2. Thereby, the first gate contact finger 7 and the second gate contact finger 9 are provided in series within the same electrically conductive channel 15. In contrast, with the field effect transistor layout of FIG. 1A, two separate transistors might be used to achieve a similar effect, wherein more space for the transistor area 2 would be needed. Therefore, the field effect transistor 1 including the first gate contact finger 7 and the second gate contact finger 9 arranged in the same active region 10 can save space on the die. This can also reduce costs. Furthermore, instead of using two separate transistors, the single transistor configuration results in less routing parasitics.

FIG. 2 shows a schematic top view diagram of a field effect transistor 1 according to another embodiment.

The field effect transistor 1 in the layout of FIG. 2 is integrated within an associated transistor area 2 on a die. The field effect transistor 1 comprises transistor contacts for electrical connection to an external circuitry. The transistor contacts comprise a drain contact 3, a first gate contact with four electrically connected first gate contact fingers 7-1, 7-2, 7-3, 7-4, a second gate contact with four electrically connected second gate contact fingers 9-1, 9-2, 9-3, 9-4, and a source contact 4.

The transistor contacts have a contact configuration of cascoded contact fingers which are arranged in an active region 10 of the field effect transistor 1. The cascoded contact fingers comprise in the illustrated embodiment of FIG. 2 three drain contact fingers 3-1, 3-2, 3-3. Two drain contact fingers 3-1, 3-3 are located at opposite edges of the transistor area 2, for example. As can be seen, the drain contact fingers 3-1, 3-2, 3-3 are connected to the drain contact 3 of the field effect transistor 1. The field effect transistor 1 further comprises the source contact 4 located on the opposite side of the drain contact 3 as shown in FIG. 2. The source contact 4 includes two source contact fingers 5-1, 5-2, for example, electrically connected to the source contact 4. Additionally, the cascoded contact fingers include the first gate contact having four first gate contact fingers 7-1, 7-2, 7-3, 7-4 electrically connected to the first gate contact. Moreover, the cascoded contact fingers include the second gate contact having four second gate contact fingers 9-1, 9-2, 9-3, 9-4 electrically connected to the second gate contact. In other embodiments, the number of cascoded contact fingers can vary.

For instance, the cascoded contact fingers of the contact configuration comprise a rectangular shape as it is illustrated in FIG. 2. The width is defined in this context by the dimension of the FET contact between two adjacent fingers (in x-direction).

Further, the first gate contact fingers 7-1, 7-2, 7-3, 7-4 can have a different width than the second gate contact fingers 9-1, 9-2, 9-3, 9-4. In particular, the first contact fingers 7-1, 7-2, 7-3, 7-4 can have a lower width than the second gate contact fingers 9-1, 9-2, 9-3, 9-4.

Furthermore, the first gate contact fingers 7-1, 7-2, 7-3, 7-4 are arranged closer to the source contact fingers 5-1, 5-2 than the second gate contact fingers 9-1, 9-2, 9-3, 9-4. Consequently, the second gate contact fingers 9-1, 9-2, 9-3, 9-4 are arranged closer to the drain contact fingers 3-1, 3-2, 3-3 than the first gate contact fingers 7-1, 7-2, 7-3, 7-4.

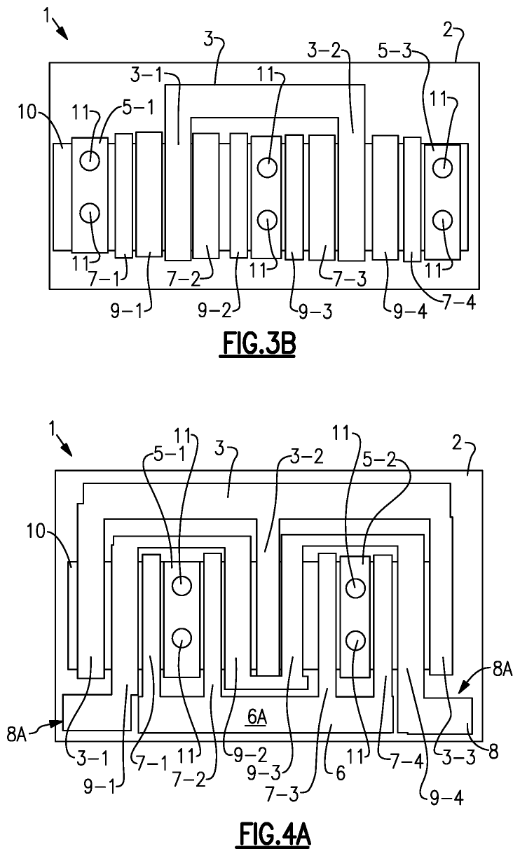

FIGS. 3A, 3B show a schematic top view diagram of a field effect transistor 1 according to another embodiment with a through wafer via 11.

The field effect transistor 1 in the layout of FIGS. 3A and 3B is integrated within an associated transistor area 2 on a die. The field effect transistor 1 comprises transistor contacts for electrical connection to an external circuitry. The transistor contacts comprise a drain contact 3, a first gate contact with four electrically connected first gate contact fingers 7-1, 7-2, 7-3, 7-4, a second gate contact with four electrically connected second gate contact fingers 9-1, 9-2, 9-3, 9-4, and a source contact at the back of the die (not visible in the top view of FIGS. 3A and 3B).

The transistor contacts have a contact configuration of cascoded contact fingers which are arranged in an active region 10 of the field effect transistor 1. The cascoded contact fingers comprise in the illustrated embodiment of FIG. 3A three drain contact fingers 3-1, 3-2, 3-3. Two drain contact fingers 3-1, 3-3 are located at opposite edges of the transistor area 2, for example. As can be seen, the drain contact fingers 3-1, 3-2, 3-3 are connected to the drain contact 3 of the field effect transistor 1. The field effect transistor 1 further comprises the source contact 4. The source contact 4 includes two source contact fingers 5-1, 5-2, for example, electrically connected to the source contact 4. Additionally, the cascoded contact fingers include the first gate contact having four first gate contact fingers 7-1, 7-2, 7-3, 7-4 electrically connected to the first gate contact. Moreover, the cascoded contact fingers include the second gate contact having four second gate contact fingers 9-1, 9-2, 9-3, 9-4 electrically connected to the second gate contact.

The cascoded contact fingers comprise in the illustrated embodiment of FIG. 3B two drain contact fingers 3-1, 3-2. As can be seen, the drain contact fingers 3-1, 3-2 are connected to the drain contact 3 of the field effect transistor 1. The field effect transistor 1 further comprises the source contact 4. The source contact 4 includes three source contact fingers 5-1, 5-2, 5-3, for example, electrically connected to the source contact 4. Two source contact fingers 5-1, 5-3 are located at opposite edges of the transistor area 2 and the active region, for example. Additionally, the cascoded contact fingers include the first gate contact 6 having four first gate contact fingers 7-1, 7-2, 7-3, 7-4 electrically connected to the first gate contact 6. Moreover, the cascoded contact fingers include the second gate contact 8 having four second gate contact fingers 9-1, 9-2, 9-3, 9-4 electrically connected to the second gate contact 8.

In FIGS. 3A and 3B, the source contact 4 is connected by through wafer vias (TWV) 11 to the source contact fingers 5-i. The through wafer vias 11 of the source contact fingers 5-i can be adapted to carry equal electric current. Therefore, by providing the source contact 4 on the back side of the die a drain capacitance can be reduced.

The die forms a small block of semiconducting material through which the given functional circuit of the field effect transistor 1 is fabricated. Integrated circuits can be produced in large batches on a single wafer in a manufacturing process. The wafer is then cut or diced into many pieces each containing a copy of the integrated circuit. The cut pieces form the die.

Optionally, the FET can comprise a pseudomorphic high-electron-mobility transistor (pHEMT). A high-electron-mobility transistor (HEMT) can be used for high frequency, high power and high temperature applications. The HEMT is a field-effect transistor incorporating a junction between two materials with different band gaps (i.e. a heterojunction) as the channel instead of a doped region. Ideally, the two different materials used for a heterojunction would have the same lattice constant (spacing between the atoms). In practice, the lattice constants are typically slightly different (e.g. AlGaAs on GaAs), resulting in crystal defects. At regular intervals, there are two teeth clump together. In semiconductors, these discontinuities form deep-level traps and greatly reduce device performance. A HEMT where this rule is violated is called a pHEMT. This is achieved by using an extremely thin layer of one of the materials-so thin that the crystal lattice simply stretches to fit the other material. This technique allows the construction of transistors with larger bandgap differences than otherwise possible, giving them better performance.

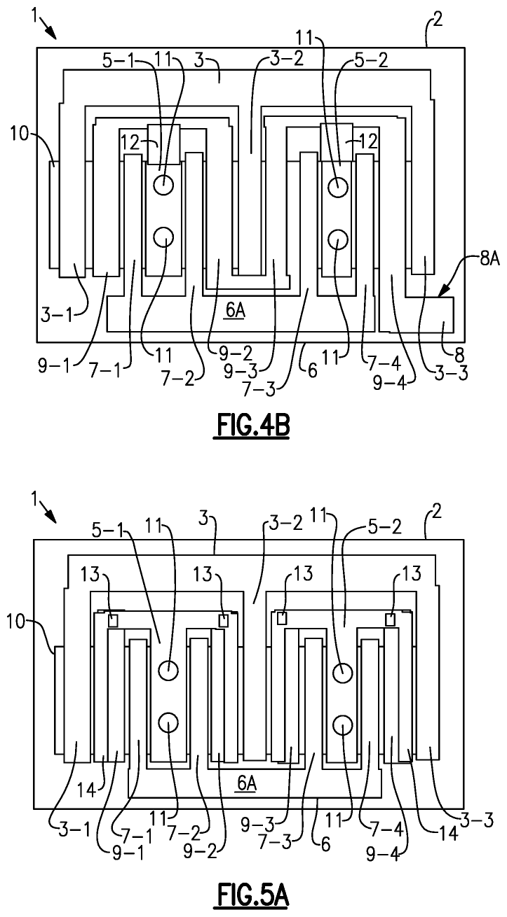

FIGS. 4A and 4B show a schematic top view diagram of a field effect transistor 1 according to another embodiment with a pad for external bias connected to the gate contact fingers, wherein the embodiment of FIG. 4B additionally comprises a metal-insulator-metal (MIM) capacitor 12.

The field effect transistor 1 in the layout of FIGS. 4A and 4B is integrated within an associated transistor area 2 on a die. The field effect transistor 1 comprises transistor contacts for electrical connection to an external circuitry. The transistor contacts comprise a drain contact 3, a first gate contact 6, a second gate contact 8, and a source contact 4 at the back of the die (not visible in the top view of FIGS. 4A and 4B).

The transistor contacts have a contact configuration of cascoded contact fingers which are arranged in an active region 10 of the field effect transistor 1. The cascoded contact fingers comprise three drain contact fingers 3-1, 3-2, 3-3. Two drain contact fingers 3-1, 3-3 are located at opposite edges of the transistor area 2, for example. As can be seen, the drain contact fingers 3-1, 3-2, 3-3 are connected to the drain contact 3 of the field effect transistor 1. The field effect transistor 1 further comprises the source contact 4. The source contact 4 includes two source contact fingers 5-1, 5-2, for example, electrically connected to the source contact 4. Additionally, the cascoded contact fingers include the first gate contact 6 having four first gate contact fingers 7-1, 7-2, 7-3, 7-4 electrically connected to the first gate contact 6. Moreover, the cascoded contact fingers include the second gate contact 8 having four second gate contact fingers 9-1, 9-2, 9-3, 9-4 electrically connected to the second gate contact 8.

In FIGS. 3A and 3B, the source contact 4 is connected by through wafer vias (TWV) 11 to the source contact fingers 5-i. The through wafer vias 11 of the source contact fingers 5-i can be adapted to carry equal electric current. Therefore, by providing the source contact 4 on the back side of the die a drain capacitance can be reduced.

Further, the first gate contact 6 includes a first pad 6A for external bias connected to the first gate contact fingers 7-i. Also, the second gate contact 8 includes a second pad 8A for external bias connected to the second gate contact fingers 9-i. In FIG. 4A the second gate contact 8 includes two second pads 8A each being arranged at the two end regions of the second gate contact 8.

Optionally, the first gate contact finger 7-i can have a different channel length than the second gate contact finger 9-i.

In the layout of FIG. 4B, the transistor contacts comprise a metal-insulator-metal (MIM) capacitor arranged between the source finger 5-1, 5-2 and the second gate contact 8. The MIM capacitor 12 is electrically connected to the second gate contact 8. Preferably, the MIM capacitor 12 is located on the opposite side of the active region 10 with regard to the first gate contact 6 and its first pad 6A, respectively. Thus, a local bypass for the second gate contact 8 can be provided.

In a possible embodiment, the field effect transistor 1 may comprise a wide bandgap transistor. This wide bandgap transistor can comprise a gallium nitride (GaN) or a silicon carbide (SiC) transistor. In a further embodiment, the field effect transistor 1 may also comprise a transistor without a wide bandgap, such as for example a GaAs transistor.

Wide bandgap semiconductors differ from conventional semiconductors in that they have a larger bandgap. The bandgap refers to the energy difference in the semiconductor between a top of the valence band and the bottom of the conduction band. A larger distance allows wide bandgap semiconductor power devices to operate at higher voltages, temperatures, and frequencies. A wide bandgap transistor can be used in a radio frequency power amplifier. Wide bandgap radio frequency power amplifiers such as those made from silicon carbide or gallium nitride offer improvements in bandwidth, power and efficiency when compared to a conventional narrow bandgap transistor.

In some embodiments, the field effect transistor 1 may comprise a gallium nitride (GaN) field effect transistor. Gallium nitride field effect transistors can operate at higher temperatures and be driven with higher voltages than gallium arsenide (GaAs) transistors. The gallium nitride transistor can be integrated in a possible embodiment into a power amplifier. The field effect transistor 1 provides a high power density and high voltage breakdown. This enables the usage of the wide bandgap field effect transistor 1 having the layout as illustrated in FIGS. 1B, 2, 3A, 3B, 4A, 4B, 5A, 5B as a component within a power amplifier of a wireless device, for instance in a wireless device or a base station for a 5G application or for applications such as a radar system.

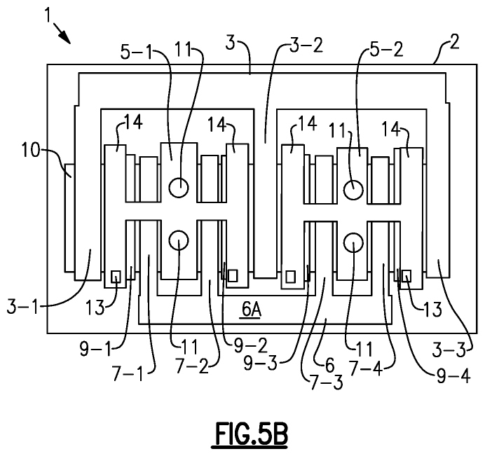

FIGS. 5A, 5B show a schematic top view diagram of a field effect transistor 1 according to another embodiment.

The field effect transistor 1 in the layout of FIGS. 5A and 5B is integrated within an associated transistor area 2 on a die. The field effect transistor 1 comprises transistor contacts for electrical connection to an external circuitry. The transistor contacts comprise a drain contact 3, a first gate contact 6, a second gate contact 8, and a source contact 4 at the back of the die (not visible in the top view of FIGS. 5A and 5B).

The transistor contacts have a contact configuration of cascoded contact fingers which are arranged in an active region 10 of the field effect transistor 1. The cascoded contact fingers comprise three drain contact fingers 3-1, 3-2, 3-3. Two drain contact fingers 3-1, 3-3 are located at opposite edges of the transistor area 2, for example. As can be seen, the drain contact fingers 3-1, 3-2, 3-3 are connected to the drain contact 3 of the field effect transistor 1. The field effect transistor 1 further comprises the source contact 4. The source contact 4 includes two source contact fingers 5-1, 5-2, for example, electrically connected to the source contact 4. Additionally, the cascoded contact fingers include the first gate contact 6 having four first gate contact fingers 7-1, 7-2, 7-3, 7-4 electrically connected to the first gate contact 6. Moreover, the cascoded contact fingers include the second gate contact 8 having four second gate contact fingers 9-1, 9-2, 9-3, 9-4 electrically connected to the second gate contact 8.

In FIGS. 5A and 5B, the source contact 4 is connected by through wafer vias (TWV) 11 to the source contact fingers 5-i. The through wafer vias 11 of the source contact fingers 5-i can be adapted to carry equal electric current. Therefore, by providing the source contact 4 on the back side of the die a drain capacitance can be reduced.

Furthermore, the transistor contacts include vias 13 for connecting the second gate contact fingers 9-i to the source contact 4. The transistor contacts comprise a source connected field plate 14 connected to the source contact finger 5-i. Therefore, the second gate contact fingers 9-i are connected to ground by the vias 13.

In FIG. 5B, the source contact fingers 5-1, 5-2 in connection with the source connected field plates 14 comprise a double T-shape. The vias 13 can be arranged at a lateral side of the active region 10 as illustrated in FIGS. 5A and 5B. For example, the vias 13 can be arranged outside the active region 10.

A GaN transistor which is in a depletion mode, that means having a negative threshold, can be biased with zero Volt on the second gate contact.

Besides a smaller die size and a reduced drain capacitance, the field effect transistor 1 in the layout of FIGS. 1B, 2, 3A, 3B, 4A, 4B, 5A, 5B provides the further advantage that a gain of the output stage of the PA can be increased which further improves a power added efficiency (PAE) of a high power PA. Furthermore, GaN transistors may suffer from effect such as drain lag that can degrade other performance factor such as a linearity of a GaN device or an error vector magnitude (EVM). Such effects can also be reduced.

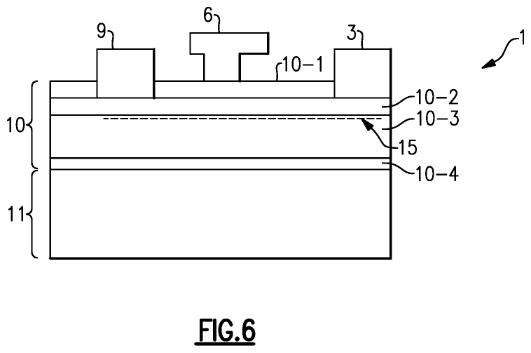

FIG. 6 shows a cross-section view of a field effect transistor 1 according to another embodiment.

In some further embodiments of the field effect transistor 1, the field effect transistor 1 can comprise a high-electron-mobility transistor (HEMT). A cross-section of the GaN HEMT field effect transistor is illustrated in FIG. 6. The exemplary high-electron-mobility transistor comprises beneath the contact configuration an epitaxial layer structure 10 grown on a substrate 11. In the illustrated embodiment of FIG. 6, the contact configuration comprises a gate contact finger 6 provided between a source contact finger 9 and a drain contact finger 3. The drain contact finger 3-i can be located at an edge of the transistor area 2.

Beneath the contact configuration, an epitaxial layer structure 10 is grown on the substrate 11. The epitaxial layer structure 10 comprises, in the illustrated embodiment, a thin cap layer 10-1 on top of an aluminum GaN barrier layer 10-2. The aluminum GaN barrier 10-2 is provided on a buffer layer 10-3. Beneath the buffer layer 10-3, a nucleation or a relaxation layer 10-4 as illustrated in the cross-section of FIG. 6 is provided. An evaporation process can be employed to create the transistor contacts.

The HEMT embodiment illustrated in FIG. 6 can be used for high frequency, high power and high temperature applications. The field effect transistor 1 occupies a small integration area when fabricated and can balance the electric current flowing through the through wafer vias 7.

Whereas in the GaN HEMT field effect transistor 1 illustrated in FIG. 6 the electrically conductive channel 15 is located beneath the AlGaN barrier 10-2, the conductive channel 15 of the MOSFET 1 shown in FIG. 6 is provided beneath the gate oxide 12.

In some embodiments, the field effect transistor 1 comprises a wide bandgap transistor and can be used in a wide range of infrastructure products such as a base station, small cells and massive MIMO (Multiple Input/Multiple Output) power amplifiers. The wide bandgap field effect transistor 1 provides a high power density so that it can comprise a smaller size and weight. It further has a high efficiency which leads to a lower power consumption and lower dissipated power or heat generation.

Further, the field effect transistor 1 implemented as a wide bandgap transistor as shown in the cross-section of FIG. 6 can provide a higher bandwidth and can provide a higher data rate. The field effect transistor 1 implemented by a wide bandgap transistor can operate at higher frequencies allowing its use in millimeter-wave applications, such as for example the Frequency Range 2 (FR2) in 5G applications. The field effect transistor 1 advantageously allows minimizing the die size for a given transistor width thus increasing the efficiency of the production process significantly. The field effect transistor 1 according to the present invention can be implemented in a power amplifier.

Accordingly, a power amplifier may comprise at least one field effect transistor 1 integrated within an associated transistor area 2, such as any of the field effect transistors shown and described with respect to FIGS. 2-6. The at least one field effect transistor 1 can comprise transistor contacts with a contact configuration of cascoded contact fingers including a first gate contact finger provided between the source contact finger and the drain contact finger, and a second gate contact finger provided between the source contact finger and the drain contact finger.

The different aspects of the field effect transistor 1 according to the present invention may also be combined with each other. The field effect transistor 1 can be used in a wide range of electronic devices. An example of the electronic devices can include, but are not limited to consumer electronic products, infrastructure devices, audio devices, parts of consumer electronic products or electronic test equipment. Examples of electronic devices can include but are not limited to memory chips, memory modules or other communication networks and disc driver circuits. The field effect transistor 1 according to the different aspects of the present invention is especially suited for telecommunication applications, in particular 5G and 6G applications.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

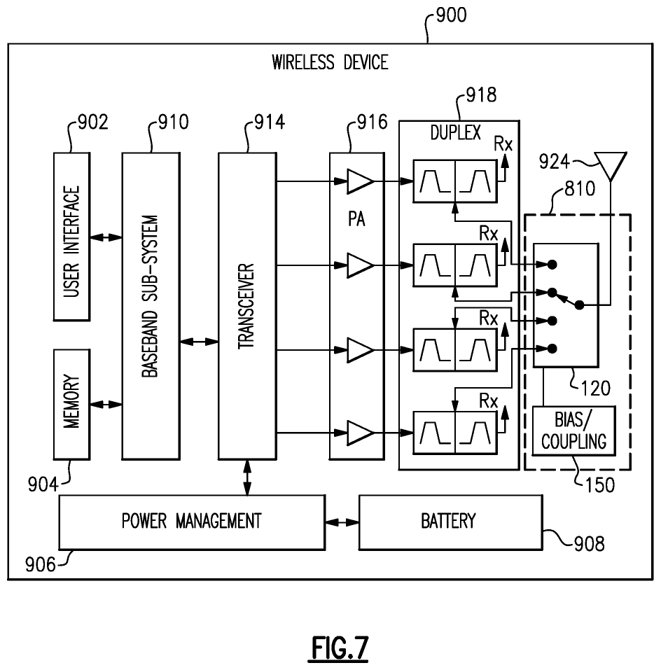

FIG. 7 shows a schematic diagram of an example wireless device 900 having one or more advantageous features described herein. In the context of various switches and various biasing/coupling configurations as described herein, a switch 120 and a bias/coupling circuit 150 can be part of a module 810. In some embodiments, such a switch module can facilitate, for example, multi-band multi p-mode operation of the wireless device 900.

In the example wireless device 900, a power amplifier (PA) module 916 having a plurality of PAs can provide an amplified RF signal to the switch 120 (via a duplexer 920), and the switch 120 can route the amplified RF signal to an antenna. The PA module 916 can receive an unamplified RF signal from a transceiver 914 that can be configured and operated in known manners. The transceiver can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 810. The PA module 916 can include one or more power amplifiers, some or all of which can include at least one field effect transistor, which can comprise any of those shown and described with respect to FIGS. 2-6.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexer 920 can allow transmit and receive operations to be performed simultaneously using a common antenna (e.g., 924). In FIG. 7, received signals are shown to be routed to “Rx” paths (not shown) that can include, for example, a low-noise amplifier, LNA.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While its specific embodiments of and examples for the invention are described above for illustrative purposes, various equivalent modifications are possible within the scope of the invention, as those skilled in the relevant art will recognize. For example, while processes or blocks are presented in a given order, alternative embodiments may perform routine and may employ systems having blocks, in a different order, or some processes or blocks may be deleted, moved, added, subdivided, combined and/or modified. Each of these blocks may be implemented in a variety of different ways.

The teaching of the present invention provided herein can be applied to other systems, not necessarily the system described above. The elements and various embodiments described above can be combined to provide further embodiments.

While certain embodiments of the present invention have been described, these embodiments have been presented by way of example only, and are not intended to limit the scope of the disclosure. Indeed, the device and system described herein may be embodied in a variety of other forms. Furthermore, various omissions, substitutions and changes in the form of the system described herein may be made without departing from the spirit of the disclosure. The accompanying claims and the equivalents are intended to cover such forms or modifications as would fall within the scope and spirit of the disclosure.

1. A field effect transistor integrated within an associated transistor area, the field effect transistor comprising transistor contacts having a contact configuration of cascoded contact fingers including a source contact finger, a drain contact finger, a first gate contact finger provided between the source contact finger and the drain contact finger, and a second gate contact finger provided between the source contact finger and the drain contact finger.

2. The field effect transistor of claim 1 wherein the cascoded contact fingers of the contact configuration have a rectangular shape.

3. The field effect transistor of claim 1 wherein the first gate contact finger has a different shape than the second gate contact finger.

4. The field effect transistor of claim 1 wherein the first gate contact finger has a different channel length than the second gate contact finger.

5. The field effect transistor of claim 1 wherein at least one of the first gate contact finger and the second gate contact finger has a T-shape.

6. The field effect transistor of claim 1 wherein the transistor contacts include a source contact located on a back side of a die, the source contact connected by a through wafer via (TWV) to the source contact finger.

7. The field effect transistor of claim 1 wherein the transistor contacts include a metal-insulator-metal (MIM) capacitor arranged between the source contact finger and a second gate contact including the second gate contact finger.

8. The field effect transistor of claim 1 wherein the first gate contact finger is arranged closer to the source contact finger than the second gate contact finger, and the second gate contact finger is arranged closer to the drain contact finger than the first gate contact finger.

9. A power amplifier comprising at least one field effect transistor integrated within an associated transistor area, the at least one field effect transistor having transistor contacts with a contact configuration of cascoded contact fingers including a source contact finger, a drain contact finger, a first gate contact finger provided between the source contact finger and the drain contact finger, and a second gate contact finger provided between the source contact finger and the drain contact finger.

10. The power amplifier of claim 9 wherein the cascoded contact fingers of the contact configuration have a rectangular shape.

11. The power amplifier of claim 9 wherein the first gate contact finger has a different shape than the second gate contact finger.

12. The power amplifier of claim 9 wherein the first gate contact finger has a different channel length than the second gate contact finger.

13. The power amplifier of claim 9 wherein at least one of the first gate contact finger and the second gate contact finger has a T-shape.

14. The power amplifier of claim 9 wherein the transistor contacts include a source contact located on a back side of a die, the source contact connected by a through wafer via, TWV, to the source contact finger.

15. The power amplifier of claim 9 wherein the transistor contacts include a metal-insulator-metal, MIM, capacitor arranged between the source contact finger and a second gate contact including the second gate contact finger.

16. The power amplifier of claim 9 wherein the first gate contact finger is arranged closer to the source contact finger than the second gate contact finger, and the second gate contact finger is arranged closer to the drain contact finger than the first gate contact finger.

17. The power amplifier of claim 9 wherein the transistor contacts include a first pad for external bias connected to the first gate contact finger.

18. The power amplifier of claim 9 wherein the transistor contacts include a second pad for external bias connected to the second gate contact finger.

19. The power amplifier of claim 9 wherein the transistor contacts include a source connected field plate.

20. A wireless device comprising:
a transceiver configured to process radio frequency signals; and
a radio frequency module including at least one field effect transistor integrated within an associated transistor area and having a contact configuration of cascoded contact fingers including a first gate contact finger provided between a source contact finger and a drain contact finger, and a second gate contact finger provided between the source contact finger and the drain contact finger.
